(19) United States
(12) Patent Application Publication
(10) Pub. No.: US 2026/0143786 A1
(43) Pub. Date: May 21, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Tefu Yeh, Kaohsiung City (TW); Jo-Chun Hung, Hsinchu City (TW); Chun-Liang Chen, Hsinchu City (TW); Chun-Cheng Chou, Taichung City (TW)

(73) Assignee: Taiwan Semiconductor Manufacturing Company, Ltd., Hsinchu (TW)

(21) Appl. No.: 18/954,647

(22) Filed: Nov. 21, 2024

(51) Int. Cl. H01L 21/8234; H01L 27/092; H01L 29/06; H01L 29/423; H01L 29/775; H01L 29/786

(52) U.S. Cl. CPC H10D 84/014; H10D 30/43; H10D 30/6735; H10D 30/6757; H10D 62/121; H10D 84/038; H10D 84/856

(57) ABSTRACT

A method, includes: forming a mask layer over a nanostructure having a plurality of vertically stacked nanosheets including a first nanosheet above a base structure of a channel region, a second nanosheet below the first nanosheet, and a third nanosheet below the second nanosheet, wherein the mask layer has a defect that leaves a portion of the nanostructure exposed; removing a first work function metal layer from around the portion of the nanostructure that is exposed; removing the mask layer; and treating the portion of the nanostructure that is exposed with an acidic chemical that removes high-K dielectric from the portion of the nanostructure that is exposed.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication including fabrication of multi-gate devices, in accordance with some embodiments.

FIGS. 2-3, 4A-4C, 5, 6A-6B, and 7-16 are schematic diagrams of a semiconductor structure at various stages of fabrication, in accordance with some embodiments.

FIG. 17 is a flowchart of an example method for forming a high-K metal gate structure in a semiconductor structure having a p-type region and an n-type region, in accordance with some embodiments.

FIGS. 18A-18B, 19A-19B, 20A-20B, 21A-21B, 22A-22B, 23A-23B, 24A-24B, 25A-25B, 26A-26B, 27A-27B, 28A-28B, and 29A-29B are schematic diagrams of a semiconductor structure at various stages of fabrication, in accordance with some embodiments.

FIGS. 30-31 are schematic diagrams illustrating a cross-sectional view of a semiconductor structure at various stages of fabrication, in accordance with some embodiments.

FIGS. 32-33 are schematic diagram illustrating a cross-sectional view of a sample semiconductor structure at various stages of metal gate batch testing, in accordance with some embodiments.

FIGS. 34-37 are schematic diagrams illustrating example measurements made in a cross-sectional view of a sample semiconductor structure during batch testing, in accordance with some embodiments.

FIG. 38-41 are schematic diagrams illustrating example angular measurements made in a cross-sectional view of a sample semiconductor structure during batch testing, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

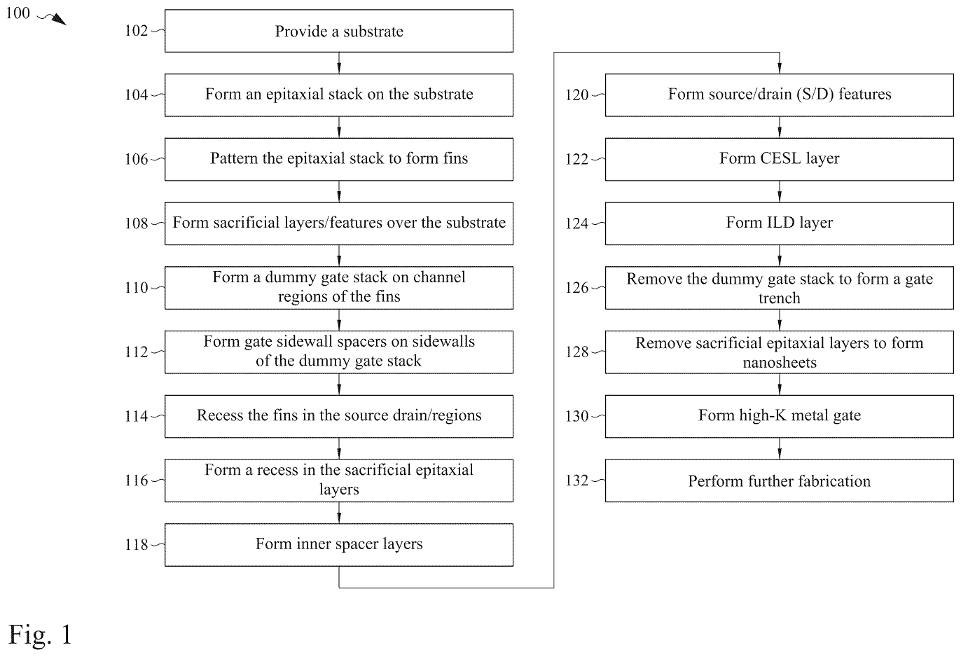

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

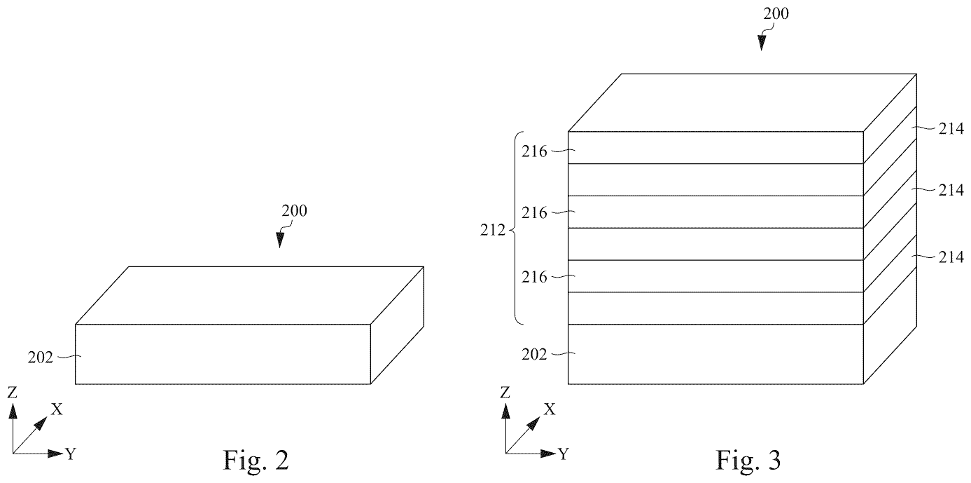

FIG. 1 is described in conjunction with FIGS. 2-3, 4A-4C, 5, 6A-6B, and 7-16, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-3, 4A-4C, 5, 6A-6B, and 7-16, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a transistor device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 then includes forming an epitaxial stack over the substrate that includes a plurality of epitaxial layers. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25^{˜}55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

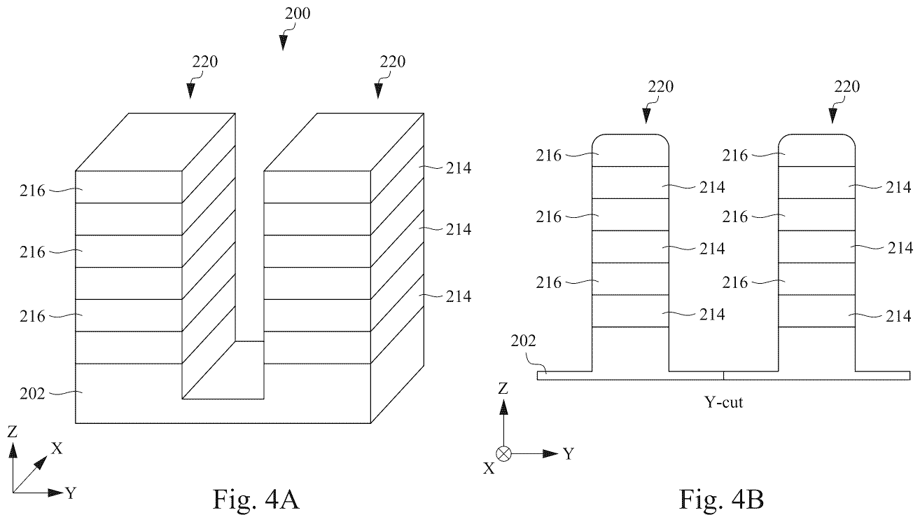

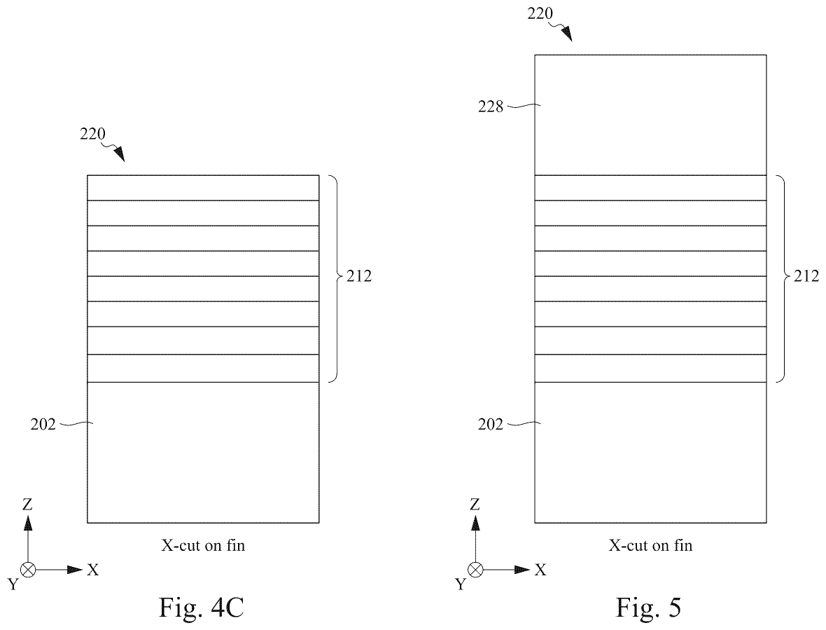

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over a stop layer 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

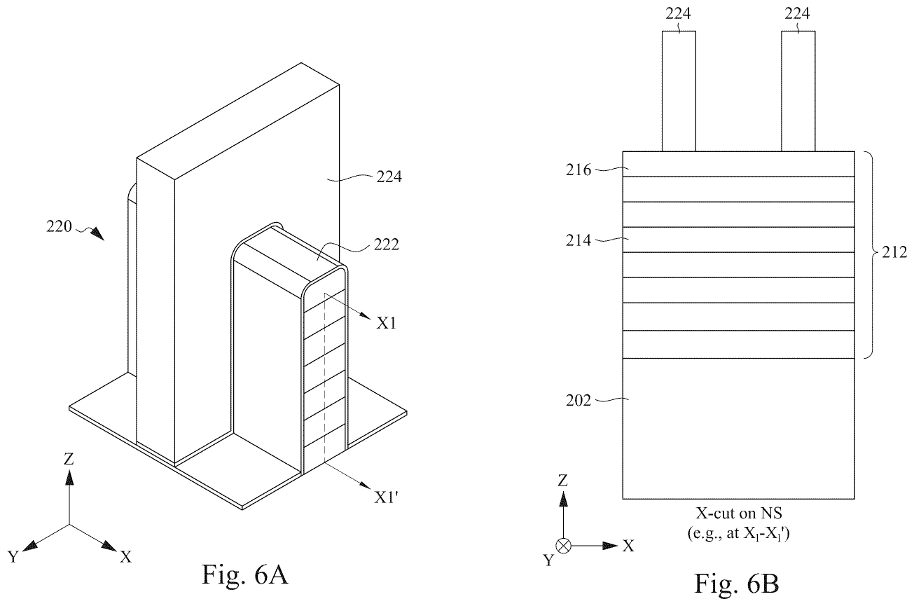

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 132 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

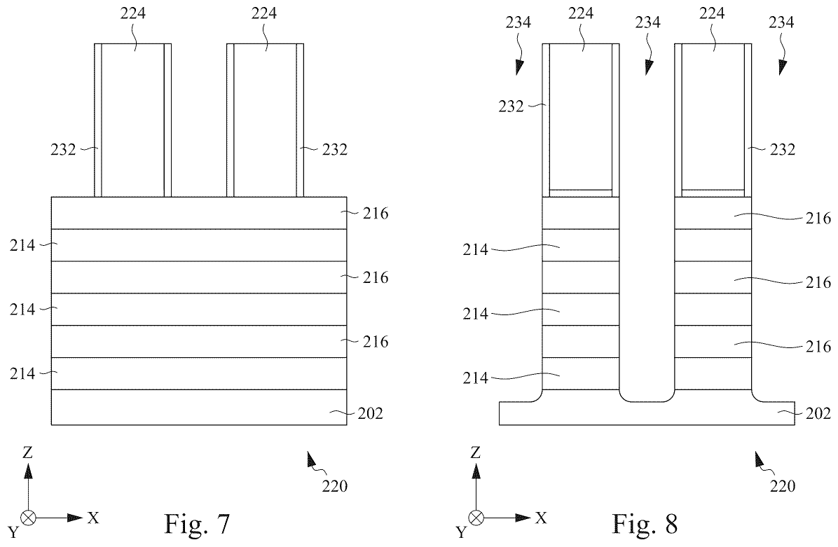

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method includes recessing the fins in the source drain/regions. Referring to the example of FIG. 8, in an embodiment of block 116, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR₃), a fluorine-containing gas (e.g., CF4, SF6, CH2F2, CHF3, and/or C2F6), other suitable gases, or combinations thereof.

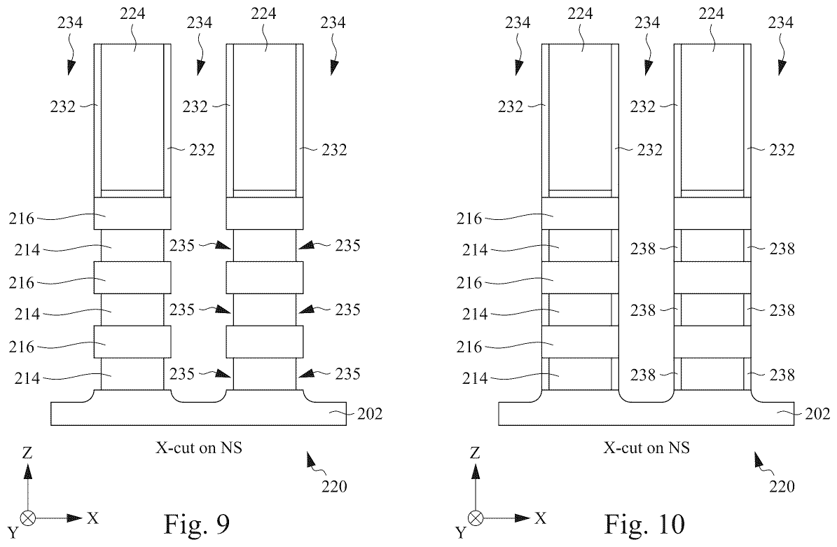

At block 116, the example method 100 includes forming a recess in the sacrificial epitaxial layers (e.g., SiGe) of the epitaxial stack. Referring to the example of FIG. 9, in an embodiment of block 116, the sacrificial epitaxial layers 214 have been etched back forming sacrificial epitaxial layer recesses 235 bounded on the top and bottom by channel epitaxial layers 216 and laterally by the recessed sacrificial epitaxial layers 214. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 118 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

At block 118, the example method 100 Includes forming an inner spacer layer in the sacrificial epitaxial layer recesses. Forming the inner spacer layer may include depositing inner spacer material. Referring to the example of FIG. 10, in an embodiment of block 118, an inner spacer layers 238 are formed in the sacrificial epitaxial layer recesses 235. The inner spacer layers 238 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the inner spacer layers 238 include multiple layers and/or other suitable dielectric materials. In some embodiments, the inner spacer layers 238 are deposited as a conformal layer. The inner spacer layers 238 can be formed by ALD or any other suitable method.

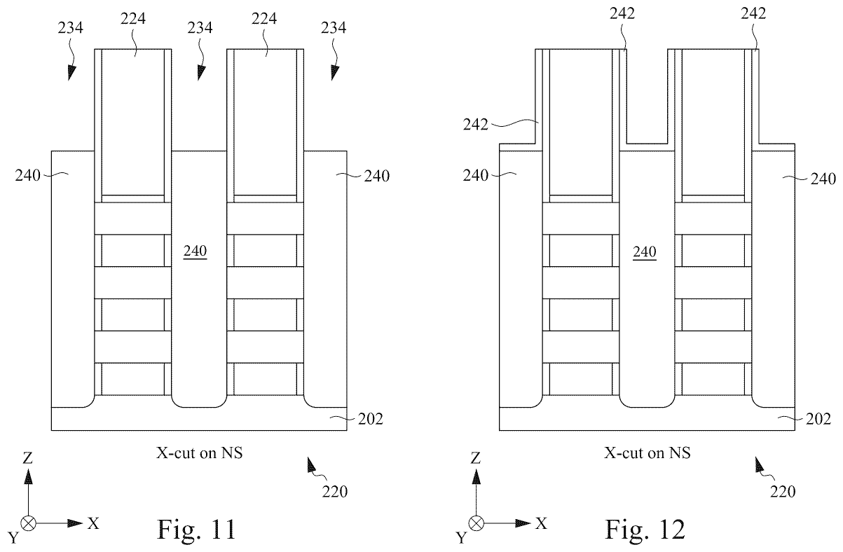

At block 120, the example method 100 includes forming source/drain (S/D) features. Referring to the example of FIG. 11, in an embodiment of block 122, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacer layers 238.

At block 122, the example method 100 includes forming a CESL layer. Referring to the example of FIG. 12, in an embodiment of block 124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

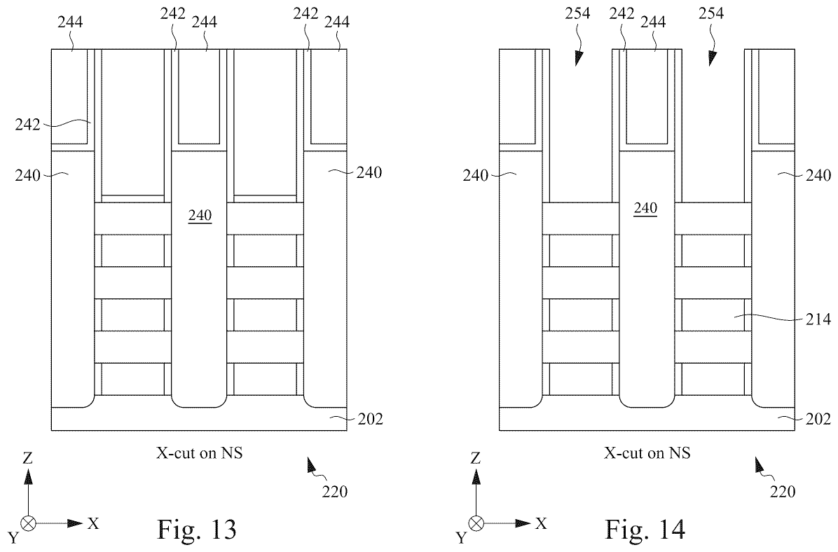

At block 124, the example method 100 includes forming an ILD layer. Referring to the example of FIG. 13, in an embodiment of block 126, an interlayer dielectric (ILD) layer 244 is formed over the CESL layer 242. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the device 200, such that the top surfaces of the sacrificial gate structure 224 are exposed.

At block 126, the example method 100 includes removing the dummy gate stack to form a gate trench. Referring to the example of FIG. 14, in an embodiment of block 128, the sacrificial gate structure 224 has been removed to form a gate trench 254. The gate trench 254 exposes the fin 220 in the channel region(s). The ILD layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD layer 244 is an oxide, a wet etchant such as a TMAH solution can be used to selectively remove the sacrificial gate electrode layer. The sacrificial gate dielectric layer is thereafter removed using plasma dry etching and/or wet etching.

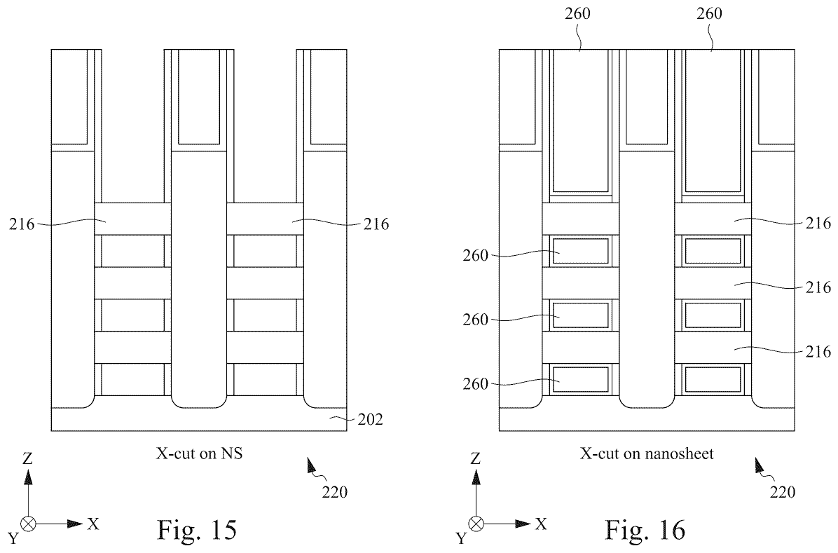

At block 128, the example method 100 includes removing the sacrificial epitaxial layers to form nanosheets. Referring to the example of FIG. 15, in an embodiment of block 130, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 130, the example method 100 includes forming high-K metal gate structures surrounding the nanostructures and over the nanostructures. In various embodiments, the gate structures are multi-layered structures. Each of the gate structures may include an interfacial layer, a gate dielectric layer, a work function layer, and a gate electrode layer. Referring to the example of FIG. 16, in an embodiment of block 132, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layers. The high-K metal gate structures may include additional material layers.

In various embodiments, multiple wafers are formed in a batch. One or more of the wafer(s) from the batch of wafers may be used as a test wafer for determining if defects occurred to PFETS in the batch of wafers during the forming of the high-K metal gate structures. In the test wafer(s), a chemical wash treatment is applied after a p-metal work function metal is formed around the PFETS and NFETS, and after the p-metal work function metal is removed from around the NFETS. The chemical wash allows defects in the PFETS to be seen more clearly in scans such as scanning electron microscope (SEM) scans. The scans of the test wafers can reveal the extent of defects to the PFETS and when the defects are within certain limits infer that the PFETS in the non-test wafers may have similar defects but the wafers are still useable and do not need to be scrapped. When the defects with the PFETS in the test wafers are not within limits, it can be inferred that the non-test wafers may have defects rendering the non-test wafers unusable. The chemical wash applied to the test wafers can provide insight into the health of PFETS in the batch of wafers and allow for the use of PFETS with defects that are within certain limits thereby increasing the yield of the wafers. This can be particularly useful for wafers having PFETS that are used in high quantity together, such as in memory arrays. Abnormalities in a few of the PFETs in a memory array does not have to doom usage of the memory array.

At block 132, the example method 100 includes performing further fabrication on the non-test wafers. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

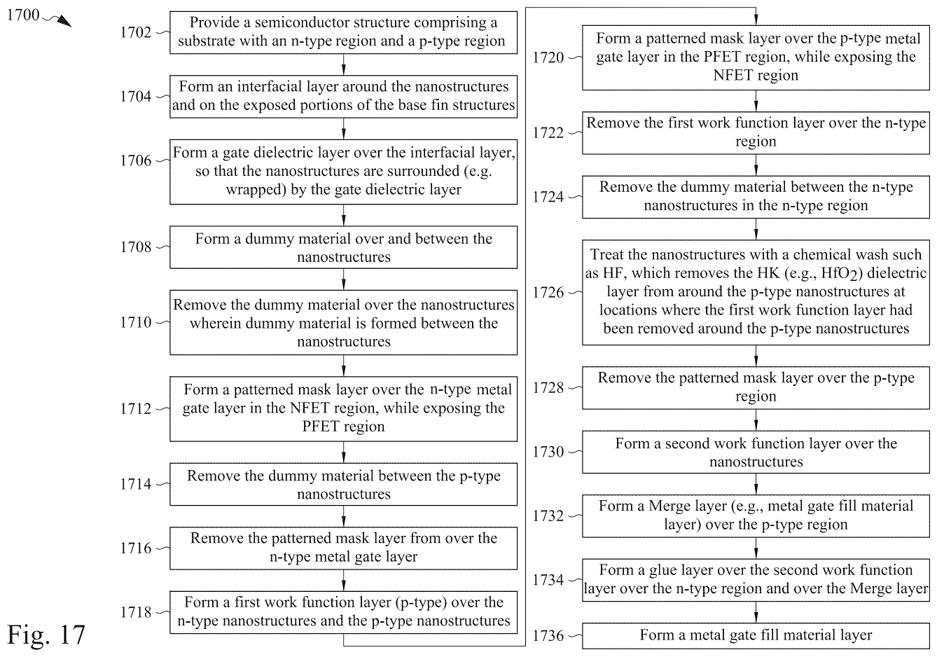

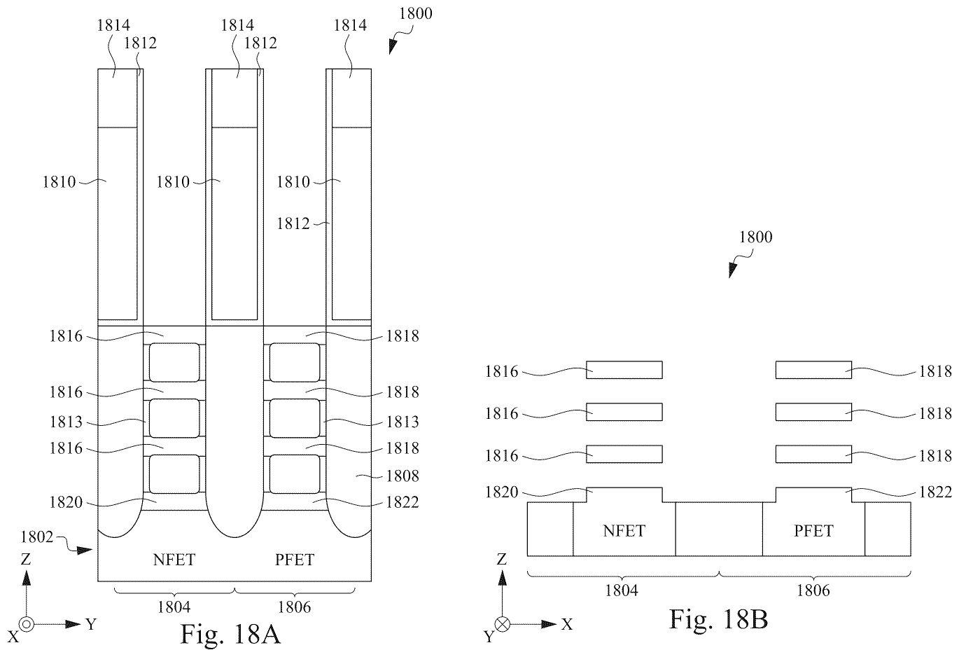

FIG. 17 is a flowchart of an example method 1700 for forming a high-K metal gate structure in a semiconductor structure having a p-type region and an n-type region, in accordance with some embodiments. FIG. 17 is described in conjunction with FIGS. 18A-18B, 19A-19B, 20A-20B, 21A-21B, 22A-22B, 23A-23B, 24A-24B, 25A-25B, 26A-26B, 27A-27B, 28A-28B, and 29A-29B, which illustrate a semiconductor structure 1800 at various stages of fabrication, in accordance with some embodiments. The method 1700 is merely an example and is not intended to limit the present disclosure beyond what is explicitly recited in the claims. Additional steps may be provided before, during, and after method 1700. As with the other method embodiments discussed herein, it is understood that parts of the semiconductor devices that may be fabricated by semiconductor technology process flow, and thus some processes are only briefly described herein.

The example method 1700 starts at block 1702 with providing a semiconductor structure 1800 comprising a substrate with an n-type region and a p-type region. Referring to the example of FIGS. 18A and 18B, a substrate 1802 is provided with an n-type region 1804 and a p-type region 1806. N-type field effect transistors (NFETs) are formed in the n-type region 1804, and p-type field effect transistors (PFETs) are formed in the p-type region 1806. The substrate 1802 includes S/D features 1808, S/D terminals 1810, spacer layers 1812, inner spacers 1813, and ILD 1814. The substrate 1802 further includes n-type nanostructures 1816, p-type nanostructures 1818, n-type base structure 1820, and p-type base structure 1822.

At block 1704, the example method 1700 includes forming an interfacial layer around the nanostructures and on the exposed portions of the base fin structures. The interfacial layer may be made of silicon oxide, and the interfacial layer may be formed by thermal oxidation. In some embodiments, the interfacial layer has a thickness in a range of about 0.5 nm to about 1.5 nm.

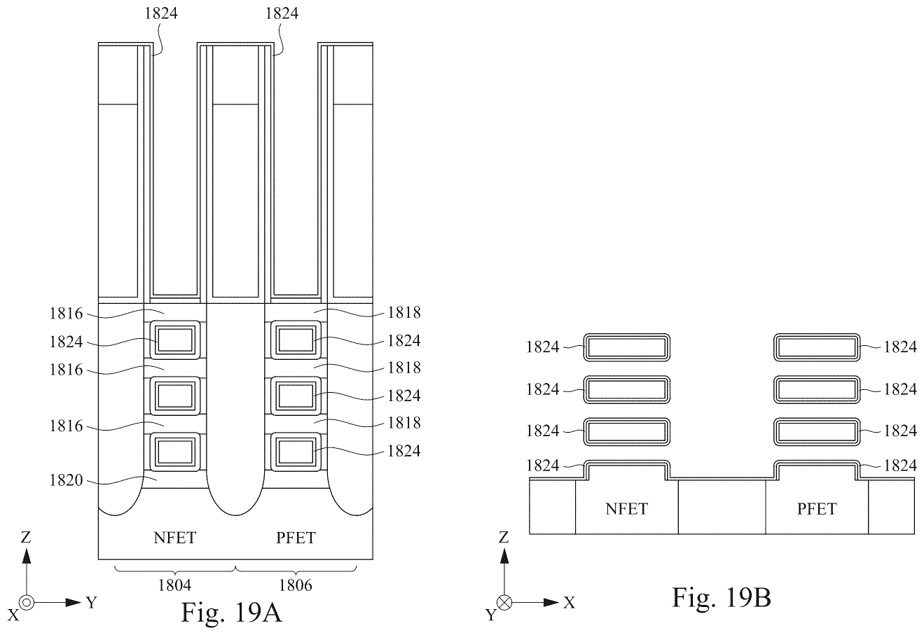

At block 1706, the example method 1700 includes forming a gate dielectric layer over the interfacial layer, so that the nanostructures are surrounded (e.g. wrapped) by the gate dielectric layer. Referring to the example of FIGS. 19A and 19B, a gate dielectric layer is formed over an interfacial layer, which wraps the n-type nanostructures 1816 and the p-type nanostructures 1818. In addition, the gate dielectric layer 1824 also covers the sidewalls of the spacer layers 1812 and the inner spacers 1813. The gate dielectric layer 1824 may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. The gate dielectric layer 1824 may be formed using CVD, ALD, other applicable methods, or a combination thereof. In some embodiments, the gate dielectric layer has a thickness in a range of about 0.5 nm to about 3 nm.

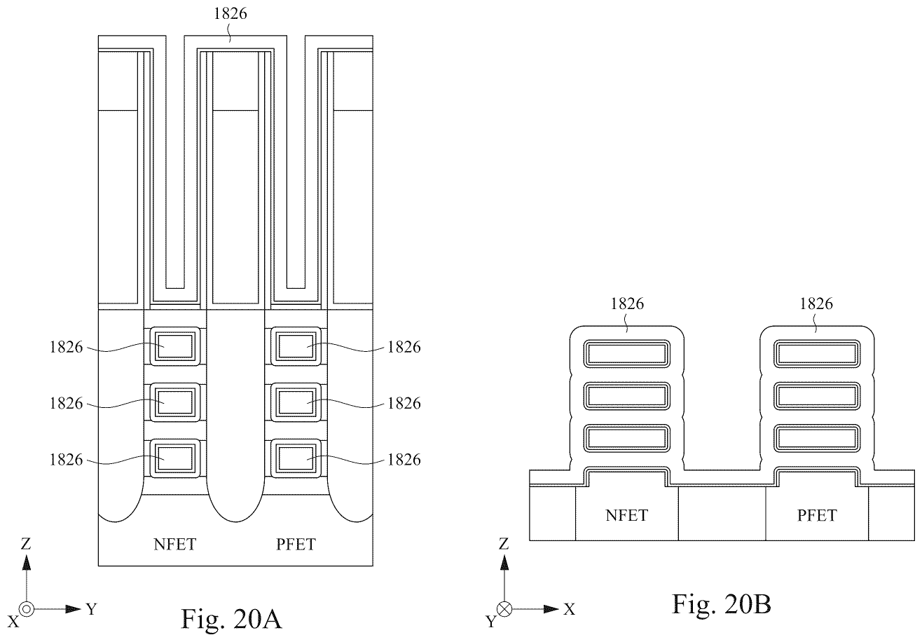

At block 1708, the example method 1700 includes forming a dummy material over and between the nanostructures. Referring to the example of FIGS. 20A and 20B, a dummy material 1826 is formed over and between the n-type nanostructures 1816 and the p-type nanostructures 1818. The dummy material 1826 may be made of metal oxides such as AlOx, GaOx, TiOx, ZnO, NiOx, (where x may be a positive integer) or metals such as TiN, TiAl, TiAlN different to gate dielectric layer, the like, or a combination thereof. The dummy material 1826 may be formed using CVD, ALD, other applicable methods, or a combination thereof.

By forming the dummy material 1826 between the n-type nanostructures 1816 and the p-type nanostructures, subsequently formed metal gate layers may not be formed between the nanostructures and it may be easier to remove the dummy material 1826 than to remove the subsequently formed metal gate layers between the n-type nanostructures 1816 and the p-type nanostructures in subsequent etching processes.

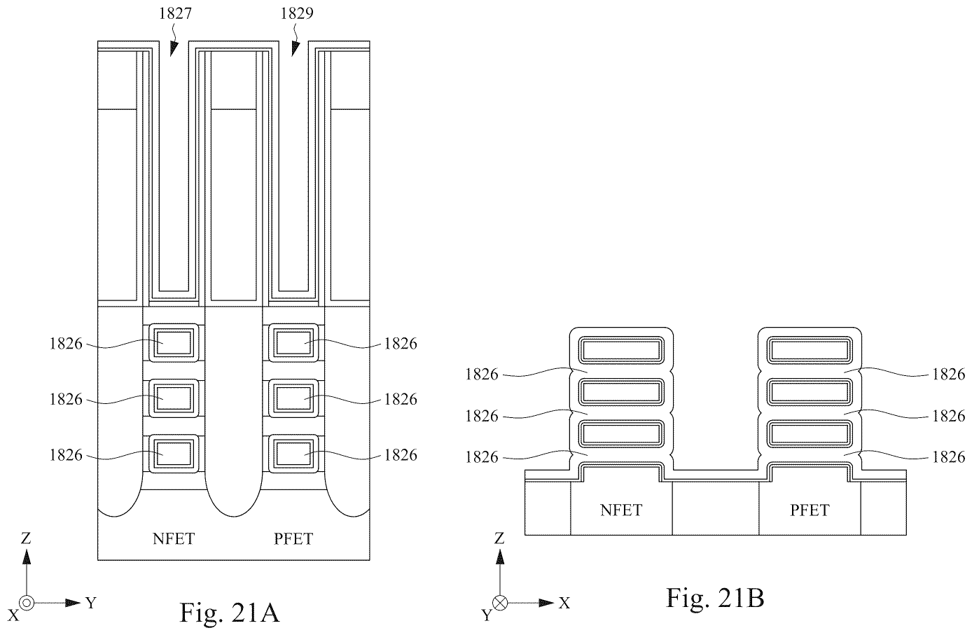

At block 1710, the example method 1700 includes removing the dummy material over the nanostructures wherein dummy material is formed between the nanostructures. Referring to the example of FIGS. 21A and 21B, dummy material 1826 is removed over the n-type nanostructures 1816 and the p-type nanostructures 1818 and removed in the NFET gate trench 1827 and in the PFET gate trench 1829. Dummy material 1826 remains formed between the n-type nanostructures 1816 and the p-type nanostructures 1818. The dummy material 1826 may be removed by an etching process. The etching process may include a dry etching process or a wet etching process.

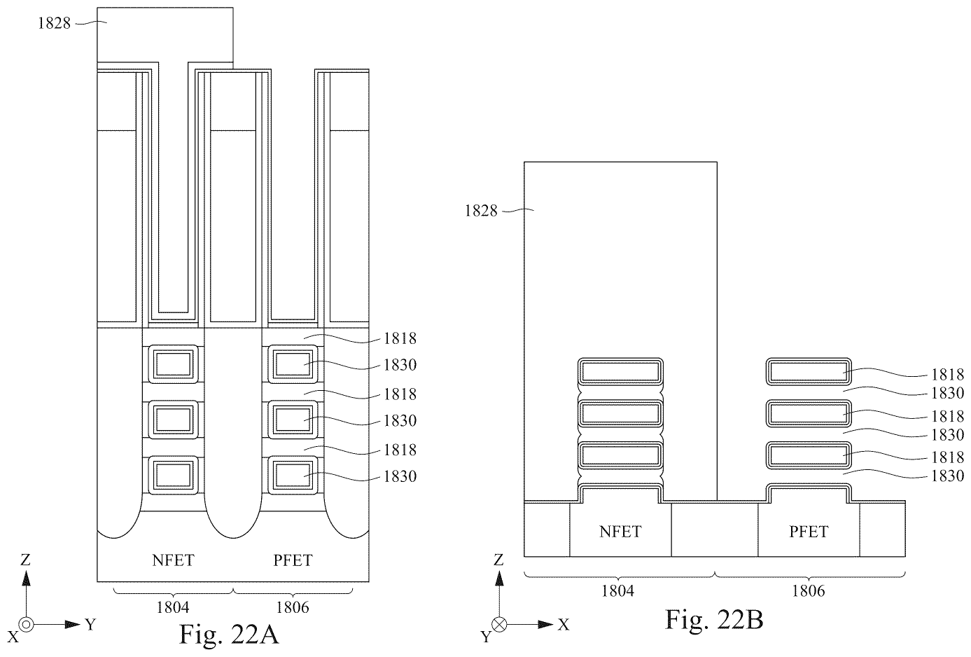

At block 1712, the example method 1700 includes forming a patterned mask layer over the n-type region, while exposing the p-type region. Referring to the example of FIGS. 22A and 22B, a patterned mask layer 1828 is formed over the NFET region 1804, while exposing the PFET region 1806. The patterned mask layer fills the NFET gate trench 1827. In various embodiments, the patterned mask layer is a patterned BARC (bottom anti-reflective coating) layer. The patterning process of forming the patterned BARC layer may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

At block 1714, the example method 1700 includes removing the dummy material between the p-type nanostructures. Referring to the example of FIGS. 22A and 22B, dummy material 1826 has been removed from between the p-type nanostructures 1818. The dummy material 1826 may be removed by an etching process. The etching process may include a dry etching process or a wet etching process. After removing the dummy material 1826 from the PFET region 1806, spaces 1830 re-appear between the adjacent channel p-type nanostructures 1818.

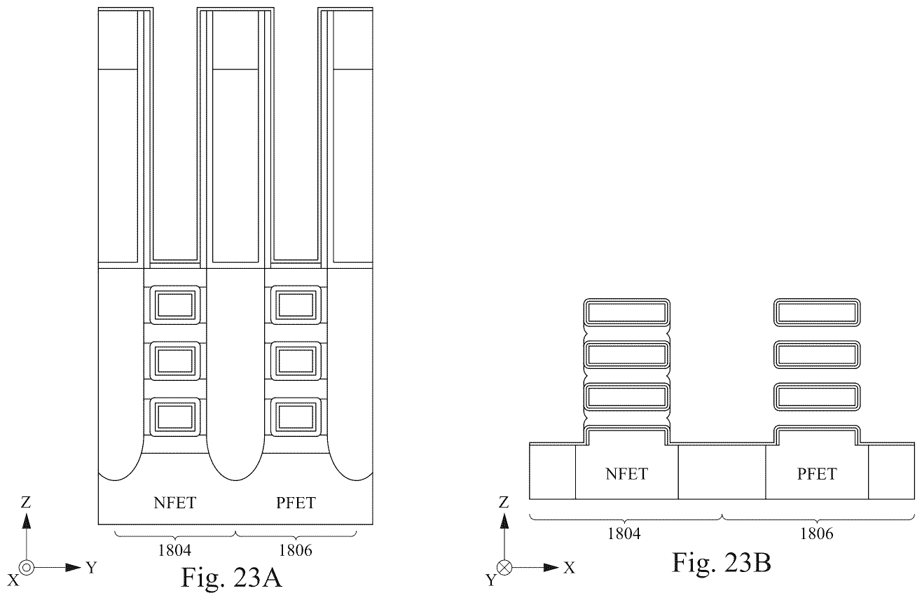

At block 1716, the example method 1700 includes removing the patterned mask layer from over the n-type metal gate layer. Referring to the example of FIGS. 23A and 23B, the patterned mask layer 1828 has been removed from the n-type region 1804 using a suitable etching process. In various embodiments, the patterned mask layer 1828 may be removed by an ashing process using N₂ and H₂.

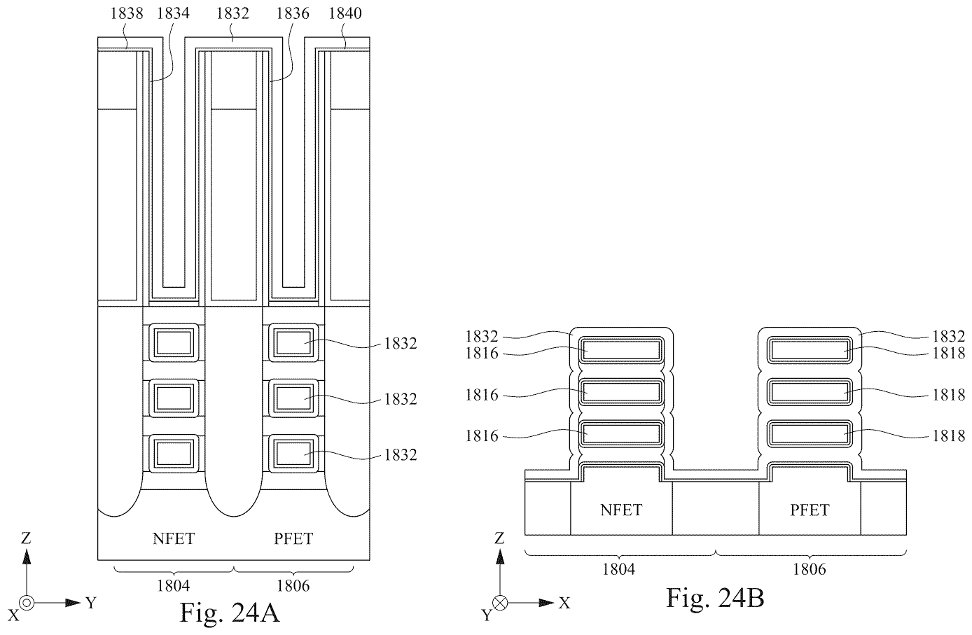

At block 1718, the example method 1700 includes forming a first work function layer (p-type) over the n-type nanostructures and the p-type nanostructures. Referring to the example of FIGS. 24A and 24B, a first work function layer 1832 (p-type) is formed over the n-type nanostructures 1816 and the p-type nanostructures 1818. The first work function layer 1832 is conformally formed over the n-type nanostructures 1816, the p-type nanostructures 1818, the sidewall structure 1834 in the n-type region 1804, the sidewall structure 1836 in the p-type region 1806, the top most surface 1838 in the n-type region 1804, and the top most surface 1840 in the p-type region 1806. The first work function layer 1832 is also conformally formed surrounding (wraps around) each of the p-type nanostructures 1818, but does not wrap around the n-type nanostructures 1816. The first work function layer 1832 merges in the spaces 1830 between adjacent p-type nanostructures 1818. In various embodiments, the first work function layer comprises a p-type work function metal. In various embodiments, the p-type work function metal comprises Ti, Al, Zn, W, Nb, Co, or others. The first work function layers may be multi-layer structures.

In various embodiments, the first work function layer 1832 is made of a metal material. In various embodiments, the first work function layer 1832 includes titanium nitride (TiN), tungsten (W), molybdenum (Mo), tungsten nitride (WN), tungsten carbon nitride (WCN), tantalum nitride (TaN), tantalum silicon nitride (TaSiN), or ruthenium (Ru) or a combination thereof. The first work function layer 1832 may be formed by a conformal deposition process such as, for example, CVD, ALD, other applicable methods, or a combination thereof. In some embodiments, the first work function layer 1832 has a thickness of about 1.0 nm to about 3.5 nm.

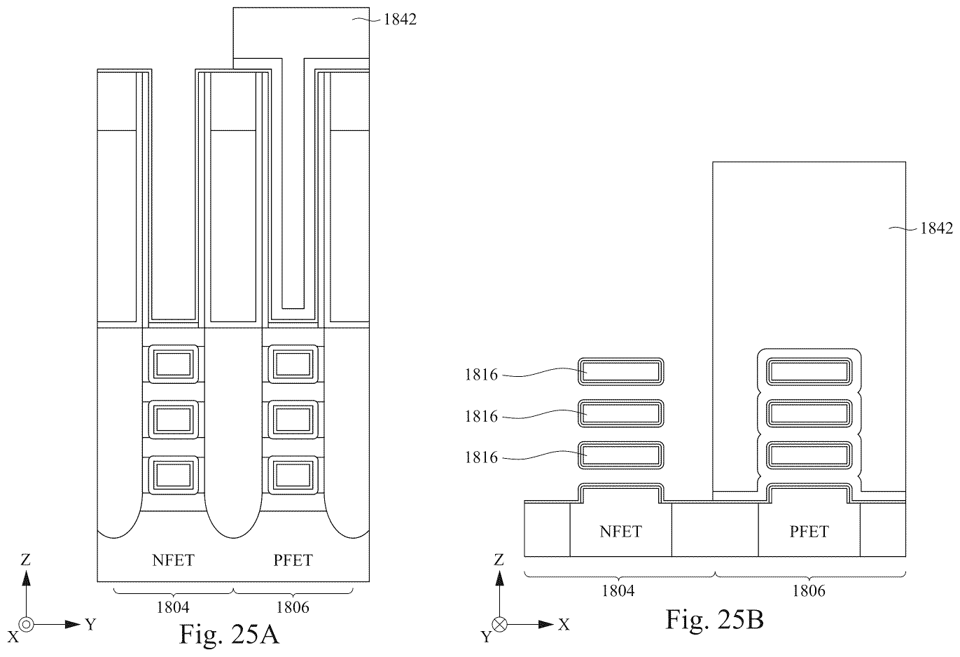

At block 1720, the example method 1700 includes forming a patterned mask layer over the p-type metal gate layer to cover a portion of the p-type metal gate layer in the PFET region, while exposing the n-type metal gate layer in the NFET region. Referring to the example of FIGS. 25A and 25B, a patterned mask layer 1842 is formed over the PFET region 1806, while exposing the NFET region 1804. The patterned mask layer fills the PFET gate trench 1829. In various embodiments, the patterned mask layer 1842 is a patterned BARC (bottom anti-reflective coating) layer. The patterning process of forming the patterned BARC layer may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

At block 1722, the example method 1700 includes removing the first work function layer over the n-type region. Referring to the example of FIGS. 25A and 25B, the first work function layer 1832 has been removed over the n-type region 1804. The first work function layer 1832 is removed from the n-type region 1804, while p-type region 1806 remains masked by the patterned mask layer 1842. In various embodiments, a wet etching process is performed to remove the first work function layer 1832 in the n-type region 1804 that is exposed by the patterned mask layer 1842. In various embodiments, the wet etching process is performed with an etchant solution, for example, an acid solution of HCl, NH₄OH or H₂SO₄ mixed with an oxidant of H₂O₂. The etching amount of the wet etching process can be adjusted by changing the etching time and temperature.

The patterned mask layer 1842 may have defects and expose parts of first work function layer 1832 around the p-type nanostructures 1818. Removing the first work function layer 1832 over the n-type nanostructures 1816 may result in removing some of the first work function layer 1832 around and between the p-type nanostructures 1818.

At block 1724, the example method 1700 includes removing the dummy material between the n-type nanostructures in the n-type region. Referring to the example of FIGS. 25A and 25B, the dummy material 1826 has been removed in the n-type region 1804 between the n-type nanostructures 1816.

The patterned mask layer 1842 may have defects and expose parts of first work function layer 1832 around the p-type nanostructures 1818. Removing the dummy material 1826 between the n-type nanostructures 1816 may result in removing some of the first work function layer 1832 around and between the p-type nanostructures 1818.

In various embodiments, multiple wafers are formed in a batch. One or more of the wafer(s) from the batch of wafers may be used as a test wafer for determining if defects occurred to PFETS in the batch of wafers during the forming of the high-K metal gate structures.

At block 1726, the example method 1700 includes treating the nanostructures in the test wafer(s) with a chemical wash such as HF, which removes the HK (e.g., HfO₂) dielectric layer from around the p-type nanostructures 1818 at locations where the first work function layer 1832 had been removed around the p-type nanostructures 1818. Treating with HF can allow the defects in the PFETs to be more visible during scans so that the extent of the defect can be assessed and a determination made regarding whether the defects are not severe enough to warrant scrapping of the batch of wafers.

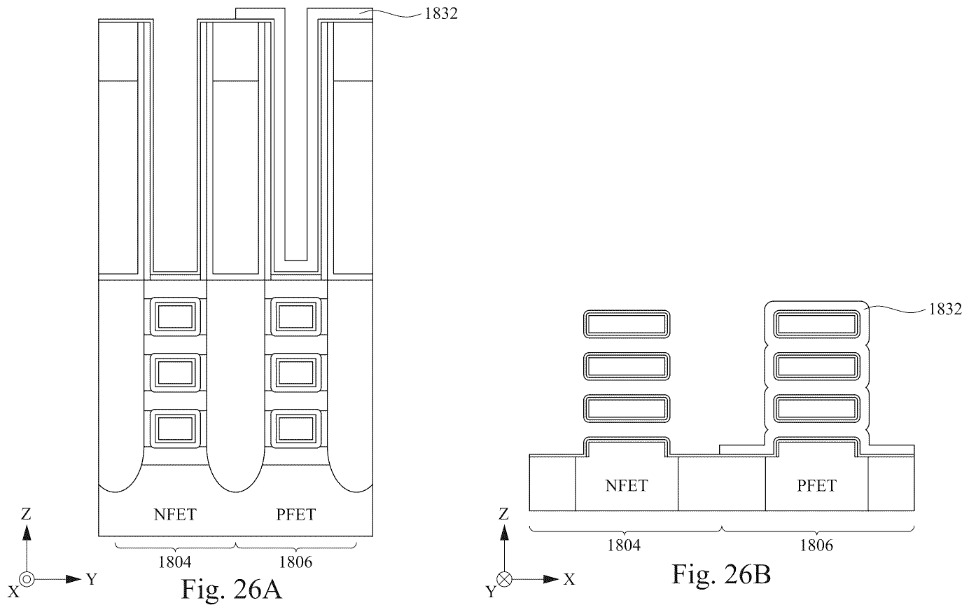

At block 1728, the example method 1700 includes removing the patterned mask layer 1842 over the p-type region 1806. Referring to the example of FIGS. 26A and 26B, the patterned mask layer 1842 has been removed from the p-type region 1806 using a suitable etching process. In various embodiments, the patterned mask layer 1842 may be removed by an ashing process using N₂ and H₂.

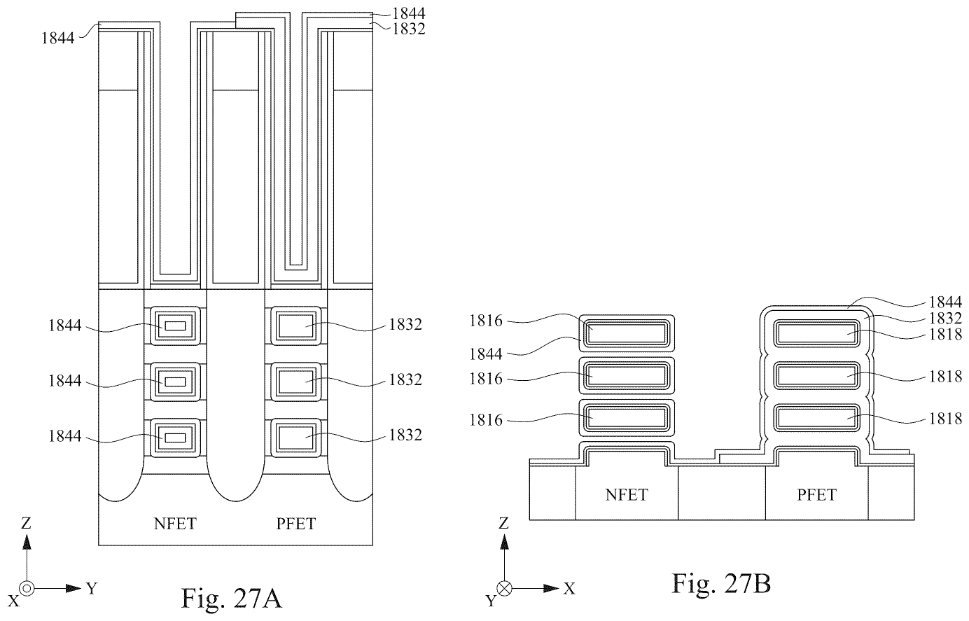

At block 1730, the example method 1700 includes forming a second work function layer over the nanostructures. Referring to the example of FIGS. 27A and 27B, the second work function layer 1844 is conformally formed over and around the n-type nanostructures 1816 and over the first work function layer 1832 over the p-type nanostructures 1818.

In various embodiments, the second work function layer 1844 comprises an n-type work function metal. In various embodiments, the n-type work function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The second work function layer may be formed by using CVD, ALD, other applicable methods, or a combination thereof. In some embodiments, the second work function layers has a thickness of about 28 Å (Angstroms) to about 40 Å in the x-direction.

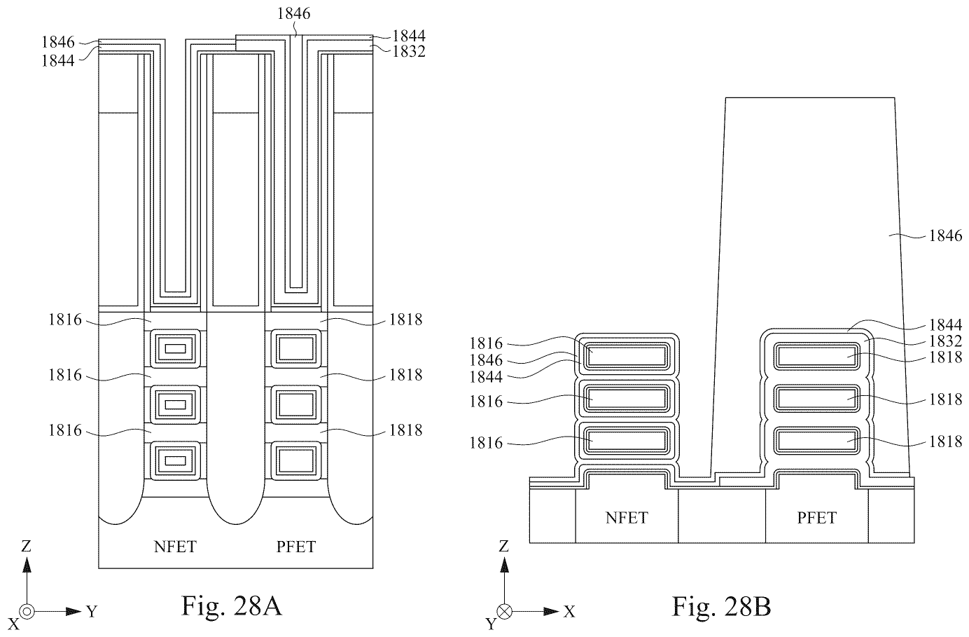

At block 1732, the example method 1700 includes forming a Merge layer over the p-type region. Referring to the example of FIGS. 28A and 28B, a Merge layer 1846 is formed over the p-type region 1806. In various embodiments, the merge layer 1846 is formed from a metal material, such as TiN or tungsten (W).

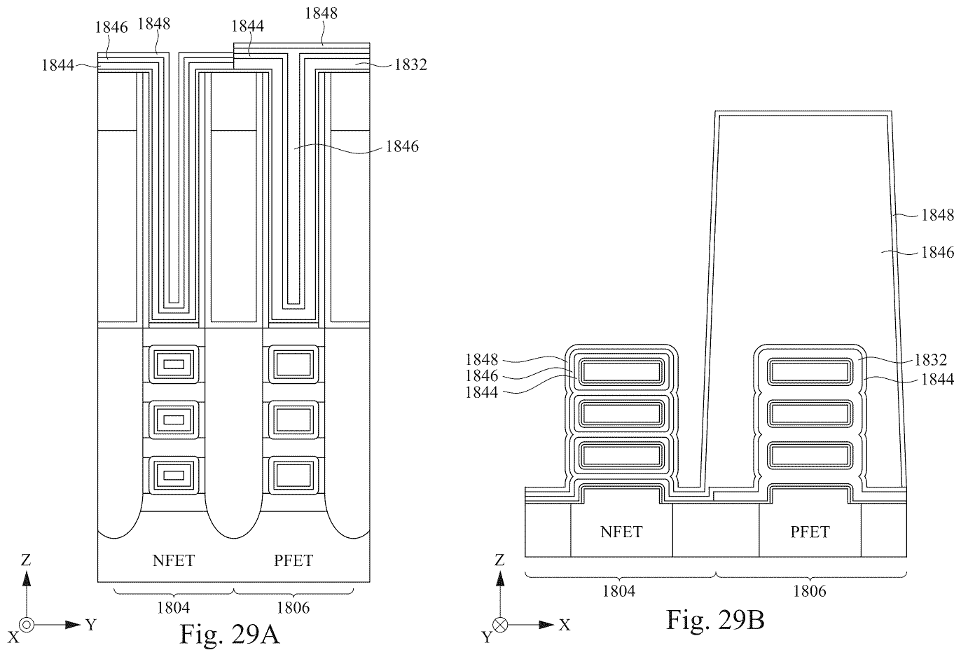

At block 1734, the example method 1700 includes forming a glue layer over the second work function layer over the p-type region and over the Merge layer. Referring to the example of FIGS. 29A and 29B, a glue layer 1848 is formed over the second work function layer 1844 over the n-type region 1804 and over the Merge layer 1846. In various embodiments, the glue layer 1848 is made of TiN, Ti, TaN, MoN, WN, other applicable materials, or a combination thereof. In various embodiments, the glue layer 1848 is formed by a chemical vapor deposition process (CVD), a physical vapor deposition process (PVD), (e.g., evaporation or sputter), an atomic layer deposition process (ALD), an electroplating process, another suitable process, or a combination thereof to deposit the conductive materials of the glue layer. Later, a planarization process or an etch back process is performed to remove excess conductive materials. In some embodiments, the top surface of the glue layer is substantially level with the top surface of the second work function layer after the planarization process.

At block 1736, the example method 1700 includes forming a metal gate fill material layer over the n-type region and a metal gate fill material layer over the p-type region. In various embodiments, the metal gate fill material layer may include tungsten (W) or cobalt (Co) and may be deposited by CVD, PVD or ALD. Thus, an n-type GAA device is formed in the n-type region 1804 and a p-type GAA device is formed in the p-type region 1806.

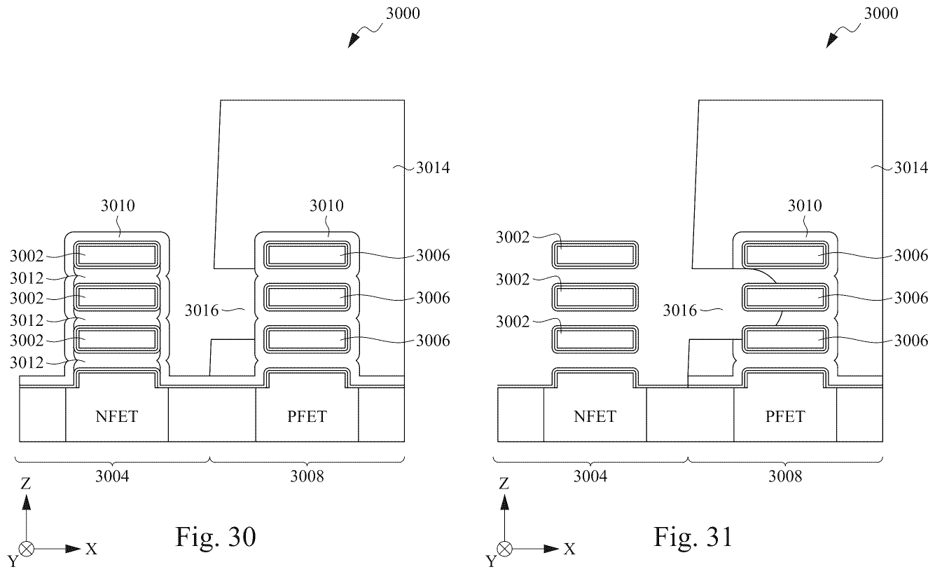

FIG. 30 is a schematic diagram illustrating a cross-sectional view of a semiconductor structure 3000 at a stage of metal gate fabrication, in accordance with some embodiments. The example semiconductor structure 3000 includes n-type nanostructures 3002 in a n-type region 3004 and p-type nanostructures 3006 in a p-type region 3008. A first work function layer 3010 (p-type) is formed over the n-type nanostructures 3002 and formed over and between the p-type nanostructures 3006. In various embodiments, the first work function layer 3010 is conformally formed over the n-type nanostructures 3002, and conformally formed over and surrounding (wraps around) the p-type nanostructures 3006. The first work function layer 3010 does not wrap around the n-type nanostructures 3002 due to dummy material 3012 disposed around the n-type nanostructures 3002. A patterned mask layer 3014 that includes a patterned BARC (bottom anti-reflective coating) layer is formed over the p-type region 3008 to protect the p-type region 3008 during a subsequent fabrication operation. In this example, the patterned mask layer 3014 has a defect area 3016 in the patterned mask layer 3014 that exposes portions of the first work function layer 3010.

FIG. 31 is a schematic diagram illustrating a cross-sectional view of the semiconductor structure 3000 at another stage of metal gate fabrication, in accordance with some embodiments. At this stage of fabrication, the first work function layer 3010 has been removed from the n-type region 3004, while p-type region 3008 remains masked by the patterned mask layer 3014. Also, the dummy material 3012 has been removed from the n-type region 3004 between the n-type nanostructures 3002. Because of the defect area 3016 in the patterned mask layer 3014, exposed portions of the first work function layer 3010 around the p-type nanostructures 3006 have also been removed during the removal of the first work function layer 3010 from around the n-type nanostructures 3002 and/or removal of the dummy material 3012 from around the n-type nanostructures 3002.

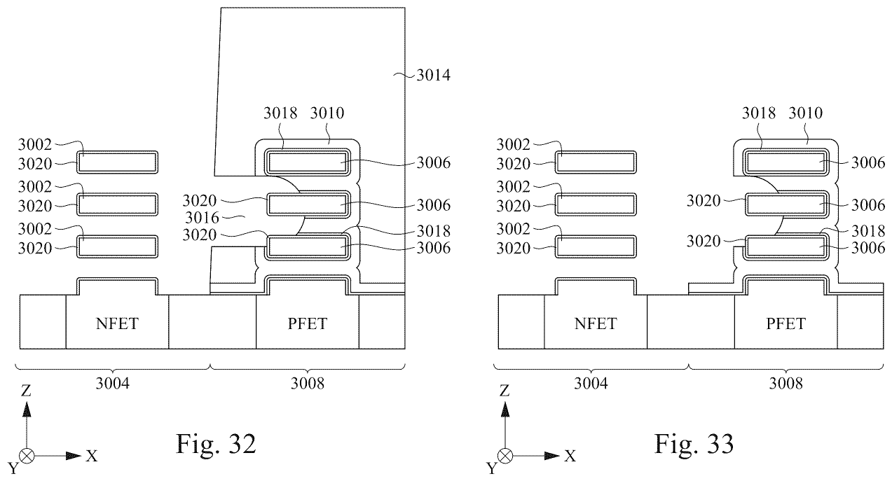

FIG. 32 is a schematic diagram illustrating a cross-sectional view of the semiconductor structure 3000 at stage of metal gate testing on a test wafer in a batch of wafers, in accordance with some embodiments. At this stage, a chemical wash has been applied to the semiconductor structure 3000. The chemical wash has removed the HK dielectric layer 3018 (e.g., HfO₂, ZrO₂, SiO₂) from around the n-type nanostructures 3002 and from around the p-type nanostructures 3006 in the defect area 3016 leaving an interfacial layer 3020 (IL) around the n-type nanostructures 3002 and the p-type nanostructures 3006. In various embodiments, the chemical wash comprises an acid chemical, such as HF, HCl, H₂SO₄, CO₂-water, HBr, in a concentration range from about 0.1 to about 10⁷ ppm.

FIG. 33 is a schematic diagram illustrating a cross-sectional view of the semiconductor structure 3000 at another stage of metal gate testing on a test wafer in a batch of wafers, in accordance with some embodiments. At this stage of fabrication, the patterned mask layer 3014 has been removed from the p-type region 3008. The portions of the p-type nanostructures 3006 that are not covered by the first work function layer 3010 have the HK dielectric layer 3018 removed. Further fabrication may be performed on the semiconductor structure 3000 of non-test wafers from the batch of wafers, and PFETs formed in the p-type region 3008 of non-test wafers from the batch of wafers in this configuration may be usable if certain physical properties related to the p-type nanostructures 3006 are met, as described in more detail below.

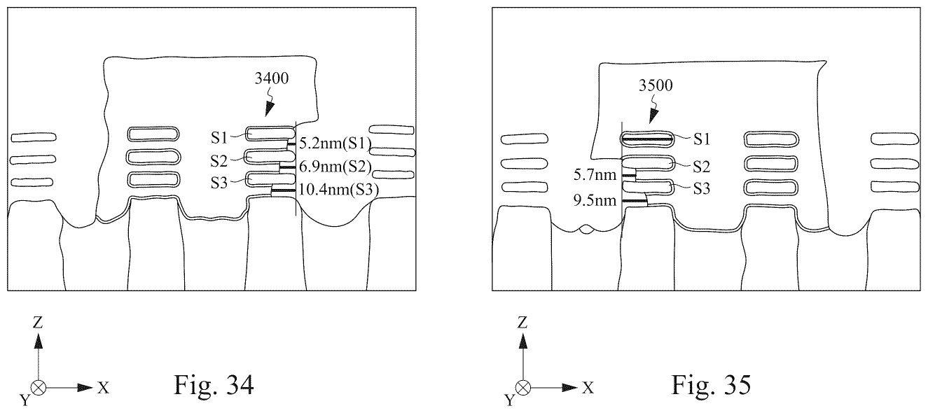

FIG. 34 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. A second work function layer has been formed in the defect area. Depicted are p-type nanostructures 3400 comprising a first nanosheet S1, a second nanosheet S2, and a third nanosheet S3. In this example, the sheet width of the first nanosheet S1, the second nanosheet S2, and the third nanosheet S3 is 19 nm. In various embodiments, the sheet width is of the nanosheet is between about 8 nm and about 70 nm. In the illustrated example, the nanostructures 3400 have a damaged area with: a horizontal length of 5.2 nm on a bottom surface of the first nanosheet S1 that is not covered by a p-type work function metal, a horizontal length of 6.9 nm on a bottom surface of the second nanosheet S2 that is not covered by the p-type work function metal, and a horizontal length of 10.4 nm on a bottom surface of the third nanosheet S3 that is not covered by the p-type work function metal. In this example, the damaged area had been treated with a chemical wash which removed the HK dielectric layer from portions of the first nanosheet S1, second nanosheet S2, and third nanosheet S3 in the damaged area. The chemical wash treatment allows the damaged area to be visible to allow assessment of the damage. When the damage is below certain limits, the PFETS are still useable.

In various embodiments, when the horizontal length of the first nanosheet in the damaged area is less than approximately 6 nm, the horizontal length of the second nanosheet in the damaged area is less than approximately 8 nm, and the horizontal length of the third nanosheet in the damaged area is less than approximately 12 nm, the PFET is useable.

In various embodiments, when the horizontal length of the first nanosheet in the damaged area is between 0 and approximately 6 nm, the horizontal length of the second nanosheet in the damaged area is between approximately 3 nm and approximately 8 nm, and the horizontal length of the third nanosheet in the damaged area is between approximately 5 and approximately 12 nm, the PFET is useable.

FIG. 35 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. A second work function layer has been formed in the defect area. Depicted are p-type nanostructures 3500 comprising a first nanosheet S1, a second nanosheet S2, and a third nanosheet S3. In this example, the sheet width of the first nanosheet S1, the second nanosheet S2, and the third nanosheet S3 is 19 nm. In various embodiments, the sheet width is of the nanosheet is between about 8 nm and about 70 nm. In the illustrated example, the nanostructures 3500 have a damaged area with: a horizontal length of 0 nm on a bottom surface of the first nanosheet S1 that is not covered by a p-type work function metal, a horizontal length of 5.7 nm on a bottom surface of the second nanosheet S2 that is not covered by the p-type work function metal, and a horizontal length of 9.5 nm on a bottom surface of the third nanosheet S3 that is not covered by the p-type work function metal. In this example, the damaged area had been treated with a chemical wash which removed the HK dielectric layer from portions of the first nanosheet S1, second nanosheet S2, and third nanosheet S3 in the damaged area. The chemical wash treatment allows the damaged area to be visible to allow assessment of the damage. Because the damage is below the certain limits, the PFETS are useable. In various embodiments, when the horizontal length of the first nanosheet in the damaged area is between 0 and approximately 6 nm, the horizontal length of the second nanosheet in the damaged area is between approximately 3 nm and approximately 8 nm, and the horizontal length of the third nanosheet in the damaged area is between approximately 5 and approximately 12 nm, the PFET is useable.

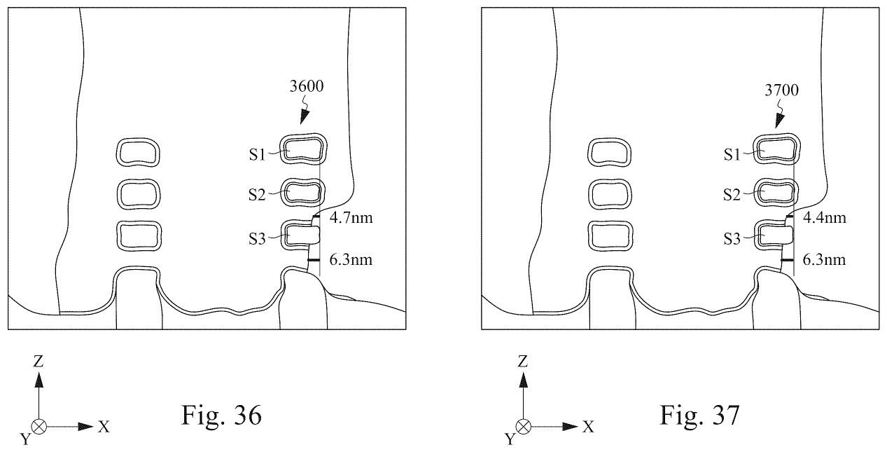

FIG. 36 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. A second work function layer has been formed in the defect area. Depicted are p-type nanostructures 3600 comprising a first nanosheet S1, a second nanosheet S2, and a third nanosheet S3. In this example, the sheet width of the first nanosheet S1, the second nanosheet S2, and the third nanosheet S3 is 11 nm. In various embodiments, the sheet width is of the nanosheet is between about 8 nm and about 70 nm. In the illustrated example, the nanostructures 3600 have a damaged area with: a horizontal length of 0 nm on a bottom surface of the first nanosheet S1 that is not covered by a p-type work function metal, a horizontal length of 4.7 nm on a bottom surface of the second nanosheet S2 that is not covered by the p-type work function metal, and a horizontal length of 6.3 nm on a bottom surface of the third nanosheet S3 that is not covered by the p-type work function metal. In this example, the damaged area had been treated with a chemical wash which removed the HK dielectric layer from portions of the first nanosheet S1, second nanosheet S2, and third nanosheet S3 in the damaged area. The chemical wash treatment allows the PFET formed from the p-type nanostructures 3600 to be used and not discarded.

FIG. 37 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. Depicted are p-type nanostructures 3700 comprising a first nanosheet S1, a second nanosheet S2, and a third nanosheet S3. In this example, the sheet width of the first nanosheet S1, the second nanosheet S2, and the third nanosheet S3 is 11 nm. In various embodiments, the sheet width is of the nanosheet is between about 8 nm and about 70 nm. In the illustrated example, the nanostructures 3700 have a damaged area with: a horizontal length of 0 nm on a bottom surface of the first nanosheet S1 that is not covered by a p-type work function metal, a horizontal length of 4.4 nm on a bottom surface of the second nanosheet S2 that is not covered by the p-type work function metal, and a horizontal length of 6.3 nm on a bottom surface of the third nanosheet S3 that is not covered by the p-type work function metal. In this example, the damaged area had been treated with a chemical wash which removed the HK dielectric layer from portions of the first nanosheet S1, second nanosheet S2, and third nanosheet S3 in the damaged area. The chemical wash treatment allows the damaged area to be visible to allow assessment of the damage. Because the damage is below the certain limits, the PFETS are useable. In various embodiments, when the horizontal length of the first nanosheet in the damaged area is between 0 and approximately 6 nm, the horizontal length of the second nanosheet in the damaged area is between approximately 3 nm and approximately 8 nm, and the horizontal length of the third nanosheet in the damaged area is between approximately 5 and approximately 12 nm, the PFET is useable.

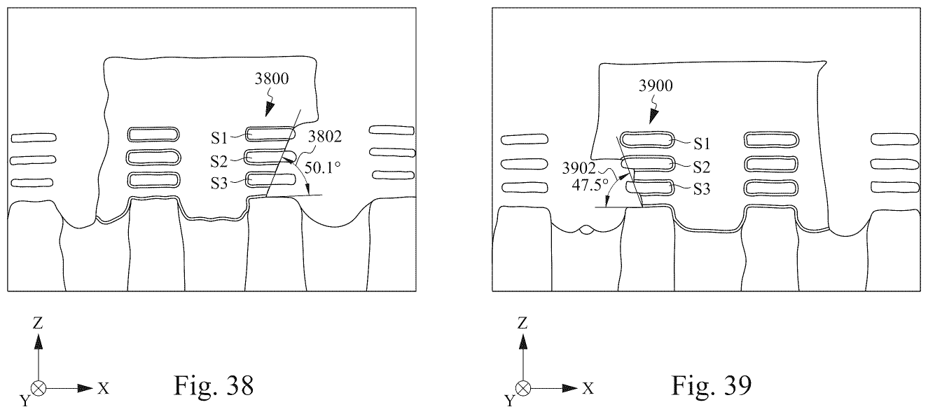

FIG. 38 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. Depicted are p-type nanostructures 3800 comprising a first nanosheet S1, a second nanosheet S2, and a third nanosheet S3. In this example, the sheet width of the first nanosheet S1, the second nanosheet S2, and the third nanosheet S3 is 19 nm. In various embodiments, the sheet width is of the nanosheet is between about 8 nm and about 70 nm. In the illustrated example, the nanostructures 3800 have a damaged area with a defect angle 3802 between a top surface of the p-type base structure and a tangent line segment that begins at an endpoint on a top surface of a topmost nanosheet (e.g., nanosheet S1) that is not covered by a p-type work function metal and extends through an endpoint on a bottom surface of a bottom most nanosheet (e.g., nanosheet S3) that is not covered by a p-type work function metal, and intersects a line extending from the top surface of the p-type base structure. In this example, the defect angle 3802 is 50.1°. The chemical wash treatment allows the damaged area to be visible to allow assessment of the damage. Because the damage is below the certain limits, the PFETS are useable. In various embodiments, when the defect angle is between approximately 40° and 90°, the PFETS are useable.

FIG. 39 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. Depicted are p-type nanostructures 3900 comprising a first nanosheet S1, a second nanosheet S2, and a third nanosheet S3. In this example, the sheet width of the first nanosheet S1, the second nanosheet S2, and the third nanosheet S3 is 19 nm. In various embodiments, the sheet width is of the nanosheet is between about 8 nm and about 70 nm. In the illustrated example, the nanostructures 3900 have a damaged area with a defect angle 3902 between a top surface of the p-type base structure and a tangent line segment that begins at an endpoint on a top surface of a topmost nanosheet (e.g., nanosheet S2) that is not covered by a p-type work function metal and extends through an endpoint on a bottom surface of a bottom most nanosheet (e.g., nanosheet S3) that is not covered by a p-type work function metal, and intersects a line extending from the top surface of the p-type base structure. In this example, the defect angle 3902 is 47.5°. The chemical wash treatment allows the damaged area to be visible to allow assessment of the damage. Because the damage is below the certain limits, the PFETS are useable. In various embodiments, when the defect angle is between approximately 40° and 90°, the PFETS are useable.

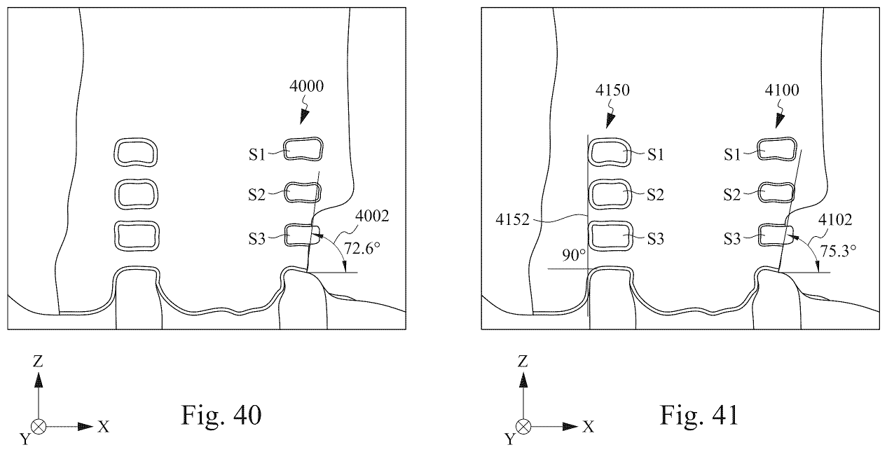

FIG. 40 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. Depicted are p-type nanostructures 4000 comprising a first nanosheet S1, a second nanosheet S2, and a third nanosheet S3. In this example, the sheet width of the first nanosheet S1, the second nanosheet S2, and the third nanosheet S3 is 11 nm. In various embodiments, the sheet width is of the nanosheet is between about 8 nm and about 70 nm.

In the illustrated example, the nanostructures 4000 have a damaged area with a defect angle 4002 between a top surface of the p-type base structure and a tangent line segment that begins at an endpoint on a top surface of a topmost nanosheet (e.g., nanosheet S2) that is not covered by a p-type work function metal and extends through an endpoint on a bottom surface of a bottom most nanosheet (e.g., nanosheet S3) that is not covered by a p-type work function metal, and intersects a line extending from the top surface of the p-type base structure. In this example, the defect angle 4002 is 72.6°. The chemical wash treatment allows the damaged area to be visible to allow assessment of the damage. Because the damage is below the certain limits, the PFETS are useable. In various embodiments, when the defect angle is between approximately 40° and 90°, the PFETS are useable.

FIG. 41 is a schematic diagram illustrating a cross-sectional view of a semiconductor structure at a stage wherein a first work function layer had been removed from an n-type region and a dummy material had been removed from the n-type region between the n-type nanostructures, all while a p-type region remained masked by a patterned mask layer, in accordance with some embodiments. Because of a defect area in the patterned mask layer, exposed portions of the first work function layer around p-type nanostructures have also been removed during the removal of the first work function layer from around the n-type nanostructures and/or removal of the dummy material from around the n-type nanostructures. Depicted are p-type nanostructures 4100 comprising a first nanosheet S1, a second nanosheet S2, and a third nanosheet S3 and p-type nanostructures 4150 comprising a first nanosheet S1, a second nanosheet S2, and a third nanosheet S3. In this example, the sheet width of the first nanosheet S1, the second nanosheet S2, and the third nanosheet S3 is 11 nm in both p-type nanostructures 4100 and p-type nanostructures 4150. In various embodiments, the sheet width is of the nanosheet is between about 8 nm and about 70 nm.

In the illustrated example, the nanostructures 4100 have a damaged area with a defect angle 4102 between a top surface of the p-type base structure and a tangent line segment that begins at an endpoint on a top surface of a topmost nanosheet (e.g., nanosheet S2) that is not covered by a p-type work function metal and extends through an endpoint on a bottom surface of a bottom most nanosheet (e.g., nanosheet S3) that is not covered by a p-type work function metal, and intersects a line extending from the top surface of the p-type base structure. In this example, the defect angle 4102 is 75.3°. The chemical wash treatment allows the damaged area to be visible to allow assessment of the damage. Because the damage is below the certain limits, the PFETS are useable. In various embodiments, when the defect angle is between approximately 40° and 90°, the PFETS are useable.

Also in the illustrated example, the nanostructures 4150 do not have a damaged area, and a defect angle 4152 is disposed between a top surface of the p-type base structure and a tangent line segment that begins at an endpoint on a top surface of a topmost nanosheet (e.g., nanosheet S1) and extends through an endpoint on a bottom surface of a bottom most nanosheet (e.g., nanosheet S3), and intersects a line extending from the top surface of the p-type base structure. In this example, the defect angle 4152 is 90°.

In some aspects, the techniques described herein relate to a method, including: providing a first nanostructure of a first type with dummy material between nanosheets of the first nanostructure and providing a second nanostructure of a second type; forming a first work function metal layer around the first nanostructure and the second nanostructure wherein the first work function metal layer forms between nanosheets of the second nanostructure but not between nanosheets of the first nanostructure; forming a mask layer over the second nanostructure, wherein the mask layer has a defect that leaves a portion of the second nanostructure exposed; removing the first work function metal layer from around the first nanostructure and the portion of the second nanostructure that is exposed, and removing the dummy material from between the nanosheets of the first nanostructure; removing the mask layer; treating the first nanostructure and the portion of the second nanostructure that is exposed with an acidic chemical that removes a high-K dielectric layer from the first nanostructure and the portion of the second nanostructure that is exposed; and measuring how much of the first work function metal layer has been removed from and around nanosheets of the second nanostructure.

In some aspects, the techniques described herein relate to a method, wherein the acidic chemical includes one or more of HF, HCl, H₂SO₄, CO₂-water, or HBr.

In some aspects, the techniques described herein relate to a method, wherein the acidic chemical has a concentration between about 0.1 ppm to 10⁷ ppm in water.

In some aspects, the techniques described herein relate to a method, wherein the first nanostructure includes an n-type nanostructure and the second nanostructure includes a p-type nanostructure.

In some aspects, the techniques described herein relate to a method, wherein: the second nanostructure includes a plurality of vertically stacked nanosheets including a first nanosheet above a base structure of a channel region, a second nanosheet below the first nanosheet, and a third nanosheet below the second nanosheet; and the third nanosheet has a covered section with a high-K dielectric layer disposed around the third nanosheet and an uncovered section without the high-K dielectric layer disposed around the third nanosheet.

In some aspects, the techniques described herein relate to a method, wherein the second nanosheet has a covered section with a high-K dielectric layer disposed around the second nanosheet and an uncovered section without the high-K dielectric layer disposed around the second nanosheet.

In some aspects, the techniques described herein relate to a method, wherein a defect angle is defined between a top surface of a base structure of a channel region and a tangent line segment that extends from an endpoint on a top surface of a topmost nanosheet of the second nanostructure that has an uncovered region through an endpoint on a bottom surface of an uncovered region in a bottom most nanosheet of the second nanostructure and the defect angle is between approximately 40° and 90°.

In some aspects, the techniques described herein relate to a semiconductor structure, including: a plurality of vertically stacked nanosheets including a first nanosheet above a base structure of a channel region, a second nanosheet below the first nanosheet, and a third nanosheet below the second nanosheet; an interfacial layer (IL) disposed around the first nanosheet, the second nanosheet, and the third nanosheet; a high-K dielectric layer disposed around at least a portion of the first nanosheet, at least a portion of the second nanosheet, and at least a portion of the third nanosheet; and the third nanosheet having a covered section with a first work function metal layer disposed over the high-K dielectric layer disposed on the IL disposed around the third nanosheet and an uncovered section without the first work function metal layer and the high-K dielectric layer disposed on the IL disposed around the third nanosheet.

In some aspects, the techniques described herein relate to a semiconductor structure, wherein the third nanosheet has a length along a bottom surface of the third nanosheet in the uncovered section that is between about 5 nm to about 12 nm.

In some aspects, the techniques described herein relate to a semiconductor structure, wherein the second nanosheet has a covered section with a first work function metal layer disposed over the high-K dielectric layer disposed on the IL disposed around the second nanosheet and an uncovered section without the first work function metal layer and the high-K dielectric layer disposed on the IL disposed around the second nanosheet.

In some aspects, the techniques described herein relate to a semiconductor structure, wherein the second nanosheet has a length along a bottom surface of the second nanosheet in the uncovered section that is between about 3 nm to about 8 nm.

In some aspects, the techniques described herein relate to a semiconductor structure, wherein the first nanosheet has a covered section with the first work function metal layer disposed over the high-K dielectric layer disposed on the IL disposed around the first nanosheet and is without an uncovered section that is without the first work function metal layer disposed over the high-K dielectric layer disposed on the IL disposed around the first nanosheet.

In some aspects, the techniques described herein relate to a semiconductor structure, wherein a defect angle is defined between a top surface of the base structure of the channel region and a tangent line segment that extends from an endpoint on a top surface of a topmost nanosheet that has an uncovered region through an endpoint on a bottom surface of an uncovered region in a bottom most nanosheet and the defect angle is between approximately 40° and 90°.

In some aspects, the techniques described herein relate to a semiconductor structure, wherein the second nanosheet is the topmost nanosheet and the third nanosheet is the bottom most nanosheet.

In some aspects, the techniques described herein relate to a semiconductor structure, wherein the third nanosheet is the topmost nanosheet and the third nanosheet is the bottom most nanosheet.

In some aspects, the techniques described herein relate to a method, including: forming a mask layer over a nanostructure having a plurality of vertically stacked nanosheets including a first nanosheet above a base structure of a channel region, a second nanosheet below the first nanosheet, and a third nanosheet below the second nanosheet, wherein the mask layer has a defect that leaves a portion of the nanostructure exposed; removing a first work function metal layer from around the portion of the nanostructure that is exposed; removing the mask layer; and treating the portion of the nanostructure that is exposed with an acidic chemical that removes HK dielectric from the portion of the nanostructure that is exposed.

In some aspects, the techniques described herein relate to a method, wherein the third nanosheet has a covered section with a high-K dielectric layer disposed around the third nanosheet and an uncovered section without the high-K dielectric layer disposed around the third nanosheet.

In some aspects, the techniques described herein relate to a method, wherein the second nanosheet has a covered section with the high-K dielectric layer disposed around the second nanosheet and an uncovered section without the high-K dielectric layer disposed around the second nanosheet.

In some aspects, the techniques described herein relate to a method wherein the first nanosheet has a covered section with the high-K dielectric layer disposed around the first nanosheet and is without an uncovered section that is without the high-K dielectric layer disposed around the first nanosheet.

In some aspects, the techniques described herein relate to a method, wherein a defect angle is defined between a top surface of a base structure of a channel region and a tangent line segment that extends from an endpoint on a top surface of a topmost nanosheet of the nanostructure that has an uncovered region through an endpoint on a bottom surface of an uncovered region in a bottom most nanosheet of the nanostructure and the defect angle is between approximately 40° and 90°.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
providing a first nanostructure of a first type with dummy material between nanosheets of the first nanostructure and providing a second nanostructure of a second type;
forming a first work function metal layer around the first nanostructure and the second nanostructure wherein the first work function metal layer forms between nanosheets of the second nanostructure but not between nanosheets of the first nanostructure;
forming a mask layer over the second nanostructure, wherein the mask layer has a defect that leaves a portion of the second nanostructure exposed;
removing the first work function metal layer from around the first nanostructure and the portion of the second nanostructure that is exposed, and removing the dummy material from between the nanosheets of the first nanostructure;
removing the mask layer;
treating the first nanostructure and the portion of the second nanostructure that is exposed with an acidic chemical that removes a high-K dielectric layer from the first nanostructure and the portion of the second nanostructure that is exposed; and
measuring how much of the first work function metal layer has been removed from and around nanosheets of the second nanostructure.

2. The method of claim 1, wherein the acidic chemical comprises one or more of HF, HCl, H₂SO₄, CO₂-water, or HBr.

3. The method of claim 1, wherein the acidic chemical has a concentration between about 0.1 ppm to 10⁷ ppm in water.

4. The method of claim 2, wherein the first nanostructure comprises an n-type nanostructure and the second nanostructure comprises a p-type nanostructure.

5. The method of claim 1, wherein:
the second nanostructure comprises a plurality of vertically stacked nanosheets comprising a first nanosheet above a base structure of a channel region, a second nanosheet below the first nanosheet, and a third nanosheet below the second nanosheet; and
the third nanosheet has a covered section with a high-K dielectric layer disposed around the third nanosheet and an uncovered section without the high-K dielectric layer disposed around the third nanosheet.

6. The method of claim 5, wherein the second nanosheet has a covered section with a high-K dielectric layer disposed around the second nanosheet and an uncovered section without the high-K dielectric layer disposed around the second nanosheet.

7. The method of claim 5, wherein a defect angle is defined between a top surface of a base structure of a channel region and a tangent line segment that extends from an endpoint on a top surface of a topmost nanosheet of the second nanostructure that has an uncovered region through an endpoint on a bottom surface of an uncovered region in a bottom most nanosheet of the second nanostructure and the defect angle is between approximately 40° and 90°.

8. A semiconductor structure, comprising:
a plurality of vertically stacked nanosheets comprising a first nanosheet above a base structure of a channel region, a second nanosheet below the first nanosheet, and a third nanosheet below the second nanosheet;
an interfacial layer (IL) disposed around the first nanosheet, the second nanosheet, and the third nanosheet;
a high-K dielectric layer disposed around at least a portion of the first nanosheet, at least a portion of the second nanosheet, and at least a portion of the third nanosheet; and
the third nanosheet having a covered section with a first work function metal layer disposed over the high-K dielectric layer disposed on the IL disposed around the third nanosheet and an uncovered section without the first work function metal layer and the high-K dielectric layer disposed on the IL disposed around the third nanosheet.

9. The semiconductor structure of claim 8, wherein the third nanosheet has a length along a bottom surface of the third nanosheet in the uncovered section that is between about 5 nm to about 12 nm.

10. The semiconductor structure of claim 8, wherein the second nanosheet has a covered section with a first work function metal layer disposed over the high-K dielectric layer disposed on the IL disposed around the second nanosheet and an uncovered section without the first work function metal layer and the high-K dielectric layer disposed on the IL disposed around the second nanosheet.

11. The semiconductor structure of claim 10, wherein the second nanosheet has a length along a bottom surface of the second nanosheet in the uncovered section that is between about 3 nm to about 8 nm.

12. The semiconductor structure of claim 8, wherein the first nanosheet has a covered section with the first work function metal layer disposed over the high-K dielectric layer disposed on the IL disposed around the first nanosheet and is without an uncovered section that is without the first work function metal layer disposed over the high-K dielectric layer disposed on the IL disposed around the first nanosheet.

13. The semiconductor structure of claim 8, wherein a defect angle is defined between a top surface of the base structure of the channel region and a tangent line segment that extends from an endpoint on a top surface of a topmost nanosheet that has an uncovered region through an endpoint on a bottom surface of an uncovered region in a bottom most nanosheet and the defect angle is between approximately 40° and 90°.

14. The semiconductor structure of claim 13, wherein the second nanosheet is the topmost nanosheet and the third nanosheet is the bottom most nanosheet.

15. The semiconductor structure of claim 13, wherein the third nanosheet is the topmost nanosheet and the third nanosheet is the bottom most nanosheet.

16. A method, comprising:
forming a mask layer over a nanostructure having a plurality of vertically stacked nanosheets comprising a first nanosheet above a base structure of a channel region, a second nanosheet below the first nanosheet, and a third nanosheet below the second nanosheet, wherein the mask layer has a defect that leaves a portion of the nanostructure exposed;
removing a first work function metal layer from around the portion of the nanostructure that is exposed;
removing the mask layer; and
treating the portion of the nanostructure that is exposed with an acidic chemical that removes high-K dielectric from the portion of the nanostructure that is exposed.

17. The method of claim 16, wherein the third nanosheet has a covered section with a high-K dielectric layer disposed around the third nanosheet and an uncovered section without the high-K dielectric layer disposed around the third nanosheet.

18. The method of claim 17, wherein the second nanosheet has a covered section with the high-K dielectric layer disposed around the second nanosheet and an uncovered section without the high-K dielectric layer disposed around the second nanosheet.

19. The method of claim 18 wherein the first nanosheet has a covered section with the high-K dielectric layer disposed around the first nanosheet and is without an uncovered section that is without the high-K dielectric layer disposed around the first nanosheet.

20. The method of claim 16, wherein a defect angle is defined between a top surface of a base structure of a channel region and a tangent line segment that extends from an endpoint on a top surface of a topmost nanosheet of the nanostructure that has an uncovered region through an endpoint on a bottom surface of an uncovered region in a bottom most nanosheet of the nanostructure and the defect angle is between approximately 40° and 90°.
